(19) United States
(12) Patent Application Publication
(10) Pub. No.: US 2015/0311418 A1
(43) Pub. Date: Oct. 29, 2015

(54) Powdered Materials Attached with Molecular Glue

(71) Applicant: Evident Technologies, Troy, NY (US)

(72) Inventors: Clinton T. Ballinger, Burnt Hills, NY (US); Bed Poudel, Cohoes, NY (US); Dmitri Talapin, Riverside, IL (US); Jae Sung Son, Ulsan (KR)

(21) Appl. No.: 14/695,425

(22) Filed: Apr. 24, 2015

Related U.S. Application Data
(60) Provisional application No. 61/983,717, filed on Apr. 24, 2014.

(51) Int. Cl. H01L 35/20; B22F 3/105; B22F 3/14; B22F 3/02; H01L 35/16; H01L 35/18

(52) U.S. Cl. CPC H01L 35/20; H01L 35/16; H01L 35/18; B22F 3/14; B22F 3/02; B22F 3/105

(57) ABSTRACT

Embodiments of the invention relate generally to methods of consolidating ball milled semiconductors. In one embodiment, the invention provides a thermoelectric material with enhanced thermoelectric (TE) performance, the thermoelectric material including a population of ball-milled particles mixed with a population of inorganic nanocrystals, wherein the inorganic nanocrystals act as a glue.

### CROSS-REFERENCE TO RELATED APPLICATIONS

This application claims the benefit of co-pending U.S. Provisional Application Ser. No. 61/983,717, filed 24 Apr. 2014, which is hereby incorporated by reference herein.

### FIELD OF THE INVENTION

The present invention relates generally to a material consisting of ball milled semiconductor materials combined with a molecular glue creating a new mechanically stable electronic material.

### BACKGROUND OF THE INVENTION

In the last decade, nano- and mesostructuring of thermoelectric (TE) materials has become a new paradigm to enhance the efficiency of TE devices. Various approaches such as spinodal decomposition during solid-state synthesis and consolidation of nano-powders have been used to prepare nanostructured materials with high TE efficiency, which is characterized by the dimensionless figure-of-merit ZT=(S2σ/k)T, where σ, S, k, and T are the electrical conductivity, Seebeck coefficient, thermal conductivity, and absolute temperature, respectively. Switching from TE materials with large crystal grains to nano- and mesostructured compounds brings up fundamentally important problems related to morphological stability, grain growth, and inter-grain transport. For example, the consolidation of grains into a dense phase by spark plasma sintering or hot-pressing is often accompanied by substantial grain growth reducing the positive effect of grain boundaries. Moreover, in a granular material ZT is strongly dependent on electronic and thermal transport through the grain boundaries. At the same time, the chemistry and physics of interfaces in TE devices remains largely underexplored. This is in stark contrast to thin-film photovoltaics where grain boundaries have been studied in depth for many years. Improved passivation of CdTe grains with CdCl2 and Cu+, or CIGS grains with Na+ has doubled the efficiency of corresponding solar cells. Compared to semiconductors used in solar cells, heavily doped TE materials should be less sensitive to trapping carriers at the interfaces. However, because the electrical current path in TE devices is large (on the millimeter scale) compared to thin film solar cells (typically approximately 1000 nm), even minor interfacial resistances lead to significant losses of σ.

### SUMMARY OF THE INVENTION

The present invention relates generally to a material that acts as a molecular glue. The molecular glue can act as a glue between the particles of ball milled materials during the consolidation of the material, or between other particles included within the consolidated material. This can be applied to material used in a variety of electronic applications such as semiconductors for LEDs, solar applications, transistors, thermoelectric devices or any other semiconductor device, optical device, or electronic device that requires a P/N junction or semiconductor components in general.

### BRIEF DESCRIPTION OF THE FIGURES

FIGS. 1a and 1b illustrate a formation of an enhanced thermoelectric material according to some embodiments of the present invention.

It is noted that the drawings may not be to scale. The drawings are intended to depict only typical aspects of the invention, and therefore should not be considered as limiting the scope of the invention. In the drawings, like numbering represents like elements between the drawings. The detailed description explains embodiments of the invention, together with advantages and features, by way of example with reference to the drawings.

### DETAILED DESCRIPTION OF THE INVENTION

According to embodiments of the present invention, disclosed herein is a thermoelectric material with enhanced thermoelectric (TE) properties as compared to materials of previous embodiments. Also disclosed herein are methods of making these TE materials and applications utilizing TE materials. In some embodiments, ball milled semiconductor materials can be used with a molecular glue that binds them together into a single solid. This mix of materials can be further densified into a material of a macro dimension, for example greater than a few microns to multiple centimeters (cm), by a variety of techniques disclosed herein.

Embodiments of the invention provide methods for forming a macro material, such as centimeter-sized solid pellets of consolidated materials, that retain the material properties inherent to the ball milled starting materials that have particle sizes that are 10 microns, or in some embodiments, 1000 nm, or smaller. Typically, those skilled in the art of consolidating materials may use an inert environment or vacuum to press these materials. This can help prevent oxidation of the material. Ball milled semiconductor materials can easily undergo unwanted oxidation since they possess a high surface to volume ratio. However, oftentimes good results are obtained even when hot pressing the material in air.

In one embodiment, a particular type of ball milled semiconductor material may be obtained. Examples of such materials may include, for instance, AlX (X=N, P, As), Ag, Au, Bi, Co, Cu, Fe, Pt, Pd, Ru, Rh, Si, Sn, Ni, Ge, GaX (X=N, P, As, Sb), CuX (X=S, Se, InSe2), PbX (X=S, Se, Te), InX (X=P, As, Sb), ZnX (X=S, Se, Te), HgX (X=S, Se, Te), GeSe, CoPt, CuInGa(Se,Se)₂, Cu₂XnSn(S,Se)₄, BiX (X=S, Se, Te), CdX (X=S, Se, Te), BiₓSb_{y}Te_{z}Se_{δ} (x=0 to 2, y=0 to 2, z=0 to 3.2 and δ=0 to 1), skutterudite materials, half heusler materials, or any combination of these materials. In some instances, these ball milled semiconductors can be synthesized. In some embodiments, a plurality of different types of ball milled semiconductor materials may be utilized. The ball-milled particles can consist of a predetermined size which can include particles of approximately 10 nm to approximately 10 microns. Milling may be done by any now known or later developed milling techniques. Although ball milling is referenced throughout this disclosure, any form of milling may be utilized. In any case, the milled semiconductor can then be mixed with a molecular glue, which in some cases may be nanometer sized materials, molecules, or atomic species. For instance, the nanomaterial can be of approximately 1 nm to approximately 20 nm, or in some embodiments, approximately 2 nm to approximately 12 nm. Examples of such materials may include molecular species nanocrystals, and inorganic nanocrystals such as Sb₂X₃ (X=S, Se, Te), Sn₂X₃ (X=S, Se, Te), ZnTe, In₂Se₃, In₂Te═, CuInSe₂, CuInGaSe₂, and Zintl ions such as As₃³⁻, As₄²⁻, As₅³⁻, As₇³⁻, As₁₁³⁻, AsS₃³⁻, As₂Se₆3-, As₂Te₆³⁻, As₁₀Te₃²⁻, Au₃Te₄³⁻, Bi₃³⁻, Bi₅³⁻, Bi₇³⁻, GaTe²⁻, Ge₉²⁻, Ge₉⁴⁻, Ge₂S₆⁴⁻, HgSe₂²⁻, Hg₃Se₄²⁻, In₂Se₄²⁻, In₂Te₄²⁻, Ni₅Sb₁₇⁴⁻, Bi₅²⁻, Pb₇⁴⁻, Pb₉⁴⁻, Pb₂Sb₂²⁻, Sb₃³⁻, Sb₄²⁻, Sb₇³⁻, SbSe₄³⁻, SbTe₄⁵⁻, Sb₂Se³⁻, Sb₂Te₅⁴⁻, Sb₂Te₇⁴⁻, Sb₄Te₄⁴⁻, Sb₉Te₆³⁻, Se₂²⁻, Se₃²⁻, Se₄²⁻, Se₆²⁻, Sn₄²⁻, Sn₅²⁻, Sn₉³⁻, Sn₉⁴⁻, SnS₄⁴⁻, snTe₄⁴⁻, SnS₄Mn₂⁵⁻, Sn₂S₆⁴⁻, Sn₂Se₆⁴⁻, Sn₂Te₆⁴⁻, Sn₂Bi₂²⁻, Sn₈Sb³⁻, Te₂²⁻, Te₃²⁻, Te₄²⁻, Tl₂Te₂²⁻, TlSn₈³⁻, TlSn₈⁵⁻, TlSn₉³⁻, TlTe₂²⁻, BiₓSb_{y}Te_{z}Se_{δ} (x=0 to 2, y=0 to 2, z=0 to 3.2 and δ=0 to 1), or other nanocrystals or molecules that may act as an appropriate material when combined with BiSbTe or similar ball milled semiconductor materials to form the final material. Other examples may include Bi, Sb or Te atomic residue that may eventually act as a molecular glue between other ball milled particles when it is consolidated together. These nanomaterials may comprise nanocrystals, colloidal nanocrystals, or any other material of the nanometer size ranges disclosed herein. For instance, where the goal is to create a material with small grains but formed into a bulk structure, a skutterudite material may be used as the ball-milled material. This can be accomplished by creating micro to nano-sized particles of skutterudite materials via ball milling then mixing with an appropriate molecular glue that contains many of the same atomic species that are present in the skutterudite material; examples include, Co, Sb, Fe, As, Ca, K, and rare earth elements.

The molecular glue, according to some embodiments, may be suspended in a solution, for instance in hydrazine, in order to form an outer coating. According to some embodiments, the ball milled particles can then, subsequent to mixing, also be suspended in the same or a different solution. Typically, these solutions will be chosen for ease of evaporating the solution. The resulting mixed material including a molecular glue and ball milled particles can be dried into an agglomerated powder. This drying may result in groupings of ball milled semiconductors, with the molecular glue as interstitial molecules which can hold particles of the ball milled semiconductor material together. The groupings may include randomly sized groupings or somewhat uniform groupings of the particles of the ball milled particles. The dried powder obtained may be used as the starting point for subsequent consolidation methods as described herein. Other ball milled semiconductor powders may be utilized. However, for brevity, this same powder will be used in the descriptions.

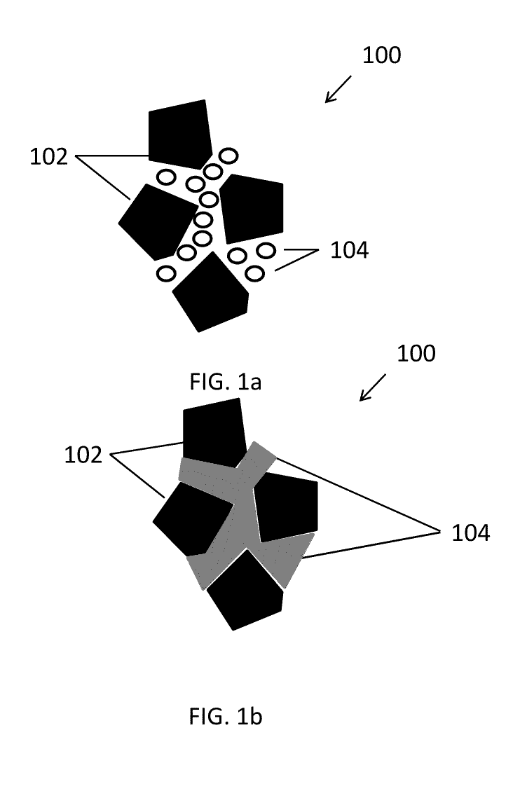

Turning to FIGS. 1a and 1b, in some embodiments, the ball-milled semiconductor 102 is demonstrated as random shapes, as the material frequently will vary in shape. Inorganic semiconductors, or molecular glue 104 are illustrated as circles. As shown in FIG. 1a, the molecular glue 104 when mixed with ball-milled particles 102 will frequently fill the interstitial spaces between particles 102. When heated or consolidated, the solvent, not shown, will be driven off and the molecular glue 104 will substantially fill the interstitial spaces creating an interface with particles 102 and improving the TE properties of the resulting material, TE material 100.

### Examples

BiₓSb₂₋ₓTe₃ provides a convenient model system to explore the effect of nanocrystal (NC) glue on TE properties. These materials exhibit high ZTs near room temperature and the dependence of their properties on compositions and structures is relatively well-understood. In this example, all-inorganic Bi NCs capped with (N₂H₅)₄Sb₂Te₇ molecular metal chalcogenide (MCC) ligands were utilized as a “glue” for the consolidation of BiSbTe ball-milled particles, as outlined in FIGS. 1a and 1b, and described above. Depending on the composition of ball-milled particles, Sb₂Te₇⁴⁻ MCC-capped Bi NCs can either increase or decrease the concentration of majority (hole) carriers near grain boundaries in BiSbTe. This enabled tuning σ, S and k towards optimal ZT values.

Bi NCs were synthesized by the reduction of bismuth n-dodecanethiolate using tri-n-octylphosphine as a mild reducing agent. The transmission electron microscopy (TEM) image of Bi NCs showed uniform ˜10 nm-sized NCs. To prepare all-inorganic NC glue for BiSbTe particles, the dodecanethiol capping ligands on as-synthesized Bi NCs were exchanged for inorganic Sb₂Te₇⁴⁻ ligands forming negatively charged NCs charge balanced with N₂H₅⁺ ions. TEM imaging showed that the ligand exchange did not affect the average size and monodispersity of Bi NCs. The X-ray diffraction (XRD) analyses of dodecanethiol-capped and Sb₂Te₇⁴⁻ MCC-capped Bi NCs showed identical patterns corresponding to that of bulk Bi, confirming no structural or size changes caused by the ligand exchange. Also, the Fourier transform infrared (FTIR) spectrum of the MCC-capped NCs showed the disappearance of the C—H stretching and bending modes that indicated almost complete replacement of the organic ligands by the inorganic ligands.

After annealing, N₂H₅⁺/Sb₂Te₇⁴⁻-capped Bi NCs formed a Bi-rich BiSbTe phase with nominal Bi_{3.2}Sb_{0.8}Te_{2.9} composition as obtained from the elemental analysis. The XRD patterns of the NCs annealed at 200° C. and 350° C. showed sharpening and a shift of the XRD peaks to higher 2θ angles. The XRD patterns of annealed NCs closely resembled a Bi₄Te₃ phase, a layered compound containing Bi₂ and Bi₂Te₃ hexagonal layers with a 1:1 ratio. Observed small shifts of some peaks to higher 2θ angles are expected due to integration of Sb³⁺ into the structure. The differential scanning calorimetry (DSC) scan showed an endothermic peak below 200° C., which was interpreted as the melting of Bi NCs followed by their reaction with Sb₂Te₇⁴⁻ surface ligands. These results indicate that the chemical reaction between Bi NCs and inorganic MCC ligands occurred below ˜200° C. and generated a Bi-rich BiSbTe phase. The thermogravimetric analysis (TGA) of Sb₂Te₇⁴⁻ MCC-capped Bi NCs showed a negligible weight loss and volume contraction at temperatures up to 450° C.

The direct sintering of BiSbTe particles requires rather high temperature (>400° C.) that causes significant grain growth. At the same time, the low reaction temperature for the formation of a BiSbTe phase from Sb₂Te₇⁴⁻-capped Bi NCs should allow “gluing” larger BiSbTe particles together at lower temperatures. To test this hypothesis, Bi NCs capped with inorganic ligands (Sb₂Te₇⁴⁻ ions) were combined with Bi_{0.5}Sb_{1.5}Te₃ ball-milled particles. The NCs were well attached to the surface of particles, which suggested that the NC glue does not segregate and forms the interfaces between BiSbTe particles during consolidation. A suspension of ball-milled particles with NC glue in hydrazine was drop-cast on a glass substrate and annealed at 400° C. for 15 min, which produced a continuous BiSbTe thin film. The scanning electron microscope (SEM) images acquired demonstrated that the particles were well-fused together, with no voids between grains. It demonstrates that melted NCs filled in the voids and formed interfaces between mesoscale particles. Obtained thin films exhibited a relatively high electrical conductivity of 40028 S/m and a Seebeck coefficient of 221 μV/K, resulting in high TE power factor S²σ=19.6 μW/cm·K². In contrast, the particles in suspension without the NCs did not form a continuous film under the same conditions. After annealing at 400° C., the film composed of only particles remained similar to a powder in composition and spontaneously peeled off from the glass substrate. The SEM image showed that individual particles were only slightly sintered and multiple voids between grains were observed. These observations clearly demonstrated the “glue effect” of Sb₂Te₇⁴⁻ capped Bi NCs for ball-milled particles.

To further understand how MCC-capped NCs affect the electronic structure of interfaces and contribute to the TE characteristics of BiSbTe properties of pellets prepared with varying amounts of NC glue were observed. For the first set of samples, powder prepared by ball-milling beads with stoichiometric Bi_{0.5}Sb_{1.5}Te₃ composition (further referred to as “BST”) were used to observe the effect of NC glue on pure Bi_{0.5}Sb_{1.5}Te₃ grains. For the second set of experiments, elemental Bi, Sb, and Te with nominal composition Bi_{0.5}Sb_{1.5}Te_{3.2} (7% excess Te) were mixed together and mechanically reacted in a ball mill (further referred to as “BST:T” samples). These methods are used for producing p-type BiSbTe with small-sized grains and the optimized carrier concentration for TE applications. The XRD patterns of both particles showed widened peaks in comparison to those of bulk materials, indicating a reduced size of crystalline domains. The estimated average crystalline domain sizes by the Williamson-Hall plot were 51.4 nm for BST particles and 73.4 nm for BST:T particles. To prepare the pellets, the mixed particles with the NC glue were dried and hot-pressed for 15 min at 350° C. for BST particles and 400° C. for BST:T particles. The NC content was controllably varied from 0% to 5% in weight. Here, the hot-pressed pellets are denoted by BST# and BST:T# (# is NC content in percentage), respectively. The relative density of all BST and BST:T samples were approximately 92 to approximately 95%. XRD patterns of BST samples correspond to rhombohedral Bi_{0.5}Sb_{1.5}Te₃ patterns and no peaks related to the oxidation and impurities were observed. On the other hand, XRD patterns of BST:T samples show Bi_{0.5}Sb_{1.5}Te₃ patterns with tiny Te (101) peak, which can be attributed to excess Te. The peak intensity of Te (101) decreased with increasing NC glue contents and became negligible in BST:T3 and BST:T5 samples. This revealed the reaction between excessive Te and Sb₂Te₇⁴⁻ capped Bi NCs during heat treatment and the formation of a BiₓSb₂₋ₓTe₃ phase at the interfaces.

Hot-pressed BST samples by the energy dispersive X-ray spectroscopy (EDS) were further studied. The TEM image and EDS spectra showed that the edge region of grinded particles is Bi-rich compared with the inside region, which clearly demonstrated the formation of interfaces from Sb₂Te₇⁴⁻ capped Bi NCs between BiSbTe grains.

The studies of the hole mobility and hole concentration show that the hole concentrations (nₕ) and mobilites (μₕ) obtained from Hall measurements at 300K in samples with different amounts of NCs will vary. This demonstrated that the addition of NC glue increased nₕ in BST samples from 2.1×10¹⁹ cm⁻³ to 8.3×10¹⁹ cm⁻³. This indicates that Sb₂Te₇⁴⁻ MCC-capped Bi NCs act as the p-type dopant for BST particles. As described above, the NC glue formed Bi-rich phase at interfaces in BiSbTe. Excessive Bi atoms are known to form Bi_{Te} antisite defects in BiSbTe, creating one additional free hole per defect. In these studies, it resulted in the formation of interfaces with additional p-doping compared to the grain interior. At the same time, μₕ slowly decreased as the amount of NC glue increased, presumably due to an increased scattering of holes on ionized antisite defects.

The BST:T samples showed the opposite and weaker dependence of nₕ and μₕ on the NC content than those of BST samples, where the addition of NC glue caused a gradual decrease of nₕ. Furthermore, the μₕ increased until 3 wt. % of the NC glue content. As discussed above, the BST:T samples contained excess Te that suppressed the formation of Bi_{Te} antisite defects. Moreover, as observed in XRD patterns, this excessive Te reacted with excessive Bi from the NCs, forming near-stoichiometric BiₓSb₂₋ₓTe₃ at the interfaces with x>0.5. These interfaces can improve the electronic connectivity between grains unlike the doped interfaces with ionized defects in BST samples, which can explain the increase of μₕ of the BST:T samples. Also, in stoichiometric BiₓSb₂₋ₓTe₃ phases, nₕ generally decreases with an increase of x due to suppression of the formation of Sb_{Te} antisite defects acting as p-type dopant. Accordingly, the Sb-poor but near stoichiometric interfaces formed by reacting Bi-rich NC glue with Te-rich BST:T particles are expected to behave as de-doped or un-doped interfaces with slightly lower nₕ compared to the grain interior.

The TE properties of all BST and BST:T samples were measured at temperatures ranging from 300 K to 450 K. The additional doping of interfaces in BST samples significantly increased the overall electrical conductivity (σ), up to 110,000 S/m by introducing additional charge carriers. Near 300K, the increase of nₕ with the increase of NC content caused a decrease of the Seebeck coefficient (S). At the same time, the addition of the NC glue changed the temperature dependence of S in BST samples: S of BST0 decreased with increasing T while all samples with doped interfaces showed dS/dT>0. The Bi-rich doped interfaces in BST samples can suppress the bipolar effect and enhance S at elevated temperature.

The BST:T1 and BST:T3 samples with the interfaces de-doped or un-doped by the NC glue exhibited slightly higher or similar a compared to the BST:T0 sample, reflecting an increase in μₕ by the NC glue effect. Also, the S at room temperature generally increased with increasing the NC content, which is consistent with decreased nₕ arising from the de-doped interfaces. This increased σ or S resulted in the higher power factor of BST:T1 and BST:T3 than BST:T0. In BST:T5 sample, it showed a faster decrease of S than other samples at high temperature, which could originate from stronger bipolar contribution to S due to the low nₕ.

The thermal conductivity (k) of BST and BST:T samples were significantly reduced in comparison to those of the state-of-the-art (SOA) bulk BiSbTe due to nano- and meso-structuring. Interestingly, k of the BST0 sample showed significant temperature dependence whereas other BST samples showed almost constant k across the measured temperature range. Such behavior of k can also be attributed to a suppressed bipolar effect at this temperature range by Bi-rich doped interfaces. On the other hand, all BST:T samples showed similar behaviors to BST:T0 because of the formation of interfaces with stoichiometric BiₓSb₂₋ₓTe₃ phases.

The lattice thermal conductivity (k_{L}) of samples was calculated based on the equation of k=k_{E}+k_{L}, where k_{E} is electronic thermal conductivity estimated by the Wiedemann-Franz law of k_{E}/σ=LT.

The Lorenz number (L) of 2.0×10⁻⁸ V²/K² was used for heavily doped semiconductors. In the BST samples, the k_{L} of all BST samples with doped interfaces was strongly reduced, indicating that Bi-rich interfaces effectively scatter phonons. On the other hand, the BST:T samples exhibited similar k_{L} regardless of NC content except for the BST:T5 sample, revealing the formation of smooth interfaces with a similar phase to bulk matrix from the NC glue. The high k_{L} of BST:T5 may indicate that the smoother and thicker interfaces provided a new phonon transport channel rather than phonon scattering sites.

The dimensionless figure-of-merit ZTs for all samples were estimated from the measured σ, S, k values. In this study, the thermal conductivities of the samples were measured along the direction parallel to the pressing whereas the electrical properties were measured along the perpendicular direction. Generally, Bi₂Te₃ based materials can exhibit anisotropic thermoelectric properties due to anisotropic crystal structures. However, the anisotropy of nanostructured materials can be considerably reduced because of the random orientation of nanoparticle building blocks. BST and BST:T samples of embodiments described herein also showed the isotropic crystal structures and electrical properties, which confirm that the calculated ZT were not overestimated.

The reduced thermal conductivities and enhanced power factors of the above examples led to significantly enhanced ZT's of BST samples with doped interfaces in comparison to BST0. The highest ZT of approximately 1 was achieved by BST3 at 425 K. All BST samples with doped interfaces showed peak ZTs above 400 K, in contrast to peak ZT at 325K for BST0, likely due to the reduced bipolar effect. Above 400 K, all BST samples containing the NC glue showed higher ZT's compared to SOA bulk BiSbTe. On the other hand, BST:T1 samples exhibited similar temperature dependence of ZT to BST:T0 and the peak ZT values of other samples moved to lower temperature with increasing the NC content, which is attributable to the decrease of nₕ by the formation of de-doped interfaces. Also, the enhanced power factors of BST:T1 and BST:T3 by increased μₕ arising from the smooth interfaces led to approximately 10% higher ZT's compared to BST:T0. BST:T1 exhibited the highest ZT of 1.22 at 350 K and ZT>1 over a wide temperature range from 300 K to 425 K.

As a consequence, the formation of Bi-rich doped interfaces from the NC glue in pure Bi_{0.5}Sb_{1.5}Te₃ grains led to the change of electrical and thermal properties, resulting in the large increase of ZT at elevated temperatures. On the other hand, the de-doped interfaces with stoichiometric BiₓSb₁₋ₓTe₃ phases improved the electronic connectivity between BiSbTe grains and increased μₕ, eventually enhancing the power factors and ZT. So, the embodiments of the present invention which use all-inorganic NCs as glue for BiSbTe grains shows the diverse way to control TE properties by designing and engineering the interfaces.

In certain embodiments, it has been discovered that the TE performance of materials prepared from ball-milled BiSbTe particles mixed with inorganic NC glue has been enhanced. For example, Sb₂Te₇⁴⁻ capped Bi NCs filled up voids and interfaces between particles and joined them together by preferential sintering. The NC glue helped connect grains of TE material without applying high temperature and pressure, enabling solution processed BiSbTe thin films and pellets. The effect of the NC glue can be particularly useful for making thin-film TE modules for site-selective cooling of micro-devices. Furthermore, the NC glue can be used for selectively tailoring the doping in vicinity of the interfaces in mesostructured TE materials. Similar NC-based chemistry can be used to introduce different elements and rationally engineer both electron and phonon transport. For instance, according to some embodiments, the use of the NC glue can increase the ZT as compared to a similar bulk material by approximately 5%, or in some embodiments, by over 10%. The ZT may be equal to approximately 1, or more than 1.5.

Other materials may be used as the molecular glue as well, providing that they do not have significant residue that will degrade the overall device performance. For example, metallic nanoparticles may be added to the dry powder and melted at a temperature due to their lower relative melting point. With a low melting point, the temperature may be sufficient to melt the nanometal but not high enough to induce grain growth of the pellet. These metallic nanoparticles may be used as the molecular glue glue or in combination with other molecular glues disclosed in other embodiments.

In other embodiments, the the addition of small particles of semiconductor materials of a given stoichiometry may be mixed with the ball milled semiconductor powder, either of the same or different stoichiometry, in a solvent. Then the material can be dried and consolidated to form a final monolithic material. Examples can include ball milled semiconductor materials while other types of semiconductor particles can be used as a “glue” to give good electrical conductivity between the particles after the consolidation technique.

Another embodiment includes utilizing ball milled semiconductors with an abundance of one or more atomic species that is not stoichiometrically ideal for the semiconductor lattice. For example, ball milled Bi_{0.5}Sb_{1.5}Te_{3.5} could be utilized, where the semiconductor lattice can only incorporate Te_{3.0}, so there is excess Te in the material. In these embodiments, a well-ordered semiconductor lattice will form, especially when heated, and the excess Te will be expelled to the surface of the material as it cannot be fully incorporated into the semiconductor lattice. When mixed with other like particles, this surface Te can act as the molecular glue between the ball milled particles, either alone or in combination with other molecular glues disclosed herein. In addition, this material itself can then be used a molecular glue between much larger particles. For instance, ball milled particles of this material with excess Te on the surface can be used as a molecular glue in order to ‘glue’ together other ball-milled semiconductor particles of a larger size.

In other embodiments, a grain growth inhibitor may be added to the powder. This grain growth inhibitor can decrease the end grain size of the material as compared to the particles undergoing grain growth, which could otherwise occur. Grain growth inhibitors may include, but are not limited to, tungsten, titanium, silver, oxygen, silicon, carbon and zirconium.

In another embodiment, a partial oxidation process may be used. Ball milled semiconductors can be easy to oxidize due to their large relative surface area. However, by consolidating through hot pressing, low temperature pressing, or spark plasma sintering to create a final consolidated material while exposed to at least some environmental air, or through the introduction of at least some oxygen gas, the properties of the material may be enhanced for thermoelectric applications. As described above, it has been found that slight oxidation of the particles can inhibit the grain growth of the resulting material, thus maintaining more of the desired properties in the end material. In this case, slight oxidation refers to an amount of oxide built up on the surface that, once consolidated, will not adversely affect performance of the material. This amount may vary depending on the final consolidation method, for instance spark plasma sintering (SPS) may have more tolerance for oxidation than casting the material in a mold via evaporation of the solvents. As such, according to this embodiment, exposure to at least some oxygen during the consolidation process can be beneficial. The oxides created within the material through the oxidation of the particles may act as a grain growth inhibitor so that desired properties are preserved, without significantly reducing these effects due to control of the oxidation.

In some embodiments, the material obtained may be consolidated by any now known or later developed consolidation techniques, such as those described above in reference to partially oxidized particles. In embodiments, the consolidated material is often mechanically strong enough to withstand post processing techniques such as slicing and dicing of the material in order to get a final shaped semiconductor. This method can be applied to a powder as described in the first example above, or to a previously consolidated material, as provided by other embodiments of the present invention, to enhance the electrical conductivity properties of the material. A powder can be cold pressed into a pellet followed by an arc welding technique in order to enhance the electrical conductivity without applying any direct heat. This can be particularly useful for applications where the original properties need to be preserved. The method allows for the microstructure to survive consolidation methodologies, while enhancing the electrical conductivity. Previous methods including general melting techniques, like hot pressing, can be avoided in this embodiment, and in exchange a localized melting can be achieved.

In another embodiment, a final stratified material can be produced. For instance, a desired material for various electronic applications may be a heterostructure, such as a structure consisting of different semiconductor, insulator and/or conductive sections that together provide an optimal performance for the desired application. A method of constructing such a material is disclosed below.

A final, monolithic material can be constructed with any number of layers of constituents within the material. For example, the BiTe—SbTe powder that was discussed in previous embodiments may be added as one layer, which may be followed by another layer of the same material with different grain sizes, or by a different semiconductor material with similar or different grain sizes, or a different molecular glue, as a few examples. Further, subsequent layers may possess metallic dopants. Layers may include an insulating material. The overall layer thickness, as well as each individual layer's thickness, can be varied by adding more or less material before the consolidation of each layer or before the final consolidation. According to certain embodiments, a material can be produced including a final material of a homogeneous layer or a heterogeneous material having any number of constituent layers of various material properties and thicknesses.

These variables can lead to a very robust material technology that has applications across many industries and markets.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A thermoelectric material with enhanced thermoelectric (TE) performance, the thermoelectric material comprising:
a population of ball-milled particles mixed with a population of inorganic nanocrystals, wherein the inorganic nanocrystals act as a glue.

2. The thermoelectric material of claim 1, wherein the population of ball-milled particles comprises a semiconductor material.

3. The thermoelectric material of claim 2, wherein the population of ball-milled particles are chosen from a group consisting of: AlX (X=N, P, As), Ag, Au, Bi, Co, Cu, Fe, Pt, Pd, Ru, Rh, Si, Sn, Ni, Ge, GaX (X=N, P, As, Sb), CuX (X=S, Se, InSe2), PbX (X=S, Se, Te), InX (X=P, As, Sb), ZnX (X=S, Se, Te), HgX (X=S, Se, Te), GeSe, CoPt, CuInGa(Se,Se)₂, Cu₂XnSn(S,Se)₄, BiX (X=S, Se, Te), CdX (X=S, Se, Te), BiₓSb_{y}Te_{z}Se_{δ} (x=0 to 2, y=0 to 2, z=0 to 3.2 and δ=0 to 1), skutterudite materials, half heusler materials, and a combination thereof.

4. The thermoelectric material of claim 1, wherein the population of inorganic nanocrystals comprises a semiconductor material.

5. The thermoelectric material of claim 4, wherein the population of inorganic nanocrystals is chosen from a group consisting of: Sb₂X₃ (X=S, Se, Te), Sn₂X₃ (X=S, Se, Te), ZnTe, In₂Se₃, In₂Te═, CuInSe₂, CuInGaSe₂, and Zintl ions such as As₃³⁻, As₄²⁻, As₅³⁻, As₇³⁻, As₁₁³⁻, AsS₃³⁻, As₂Se₆3-, As₂Te₆³⁻, As₁₀Te₃²⁻, Au₃Te₄³⁻, Bi₃³⁻, Bi₅³⁻, Bi₇³⁻, GaTe²⁻, Ge₉²⁻, Ge₉⁴⁻, Ge₂S₆⁴⁻, HgSe₂²⁻, Hg₃Se₄²⁻, In₂Se₄²⁻, In₂Te₄²⁻, Ni₅Sb₁₇⁴⁻, Bi₅²⁻, Pb₇⁴⁻, Pb₉⁴⁻, Pb₂Sb₂²⁻, Sb₃³⁻, Sb₄²⁻, Sb₇³⁻, SbSe₄³⁻, SbTe₄⁵⁻, Sb₂Se³⁻, Sb₂Te₅⁴⁻, Sb₂Te₇⁴⁻, Sb₄Te₄⁴⁻, Sb₉Te₆³⁻, Se₂²⁻, Se₃²⁻, Se₄²⁻, Se₆²⁻, Sn₄²⁻, Sn₅²⁻, Sn₉³⁻, Sn₉⁴⁻, SnS₄⁴⁻, snTe₄⁴⁻, SnS₄Mn₂⁵⁻, Sn₂S₆⁴⁻, Sn₂Se₆⁴⁻, Sn₂Te₆⁴⁻, Sn₂Bi₂²⁻, Sn₈Sb³⁻, Te₂²⁻, Te₃²⁻, Te₄²⁻, Tl₂Te₂²⁻, TlSn₈³⁻, TlSn₈⁵⁻, TlSn₉³⁻, TlTe₂²⁻, BiₓSb_{y}Te_{z}Se_{δ} (x=0 to 2, y=0 to 2, z=0 to 3.2 and δ=0 to 1), and combinations thereof.

6. The thermoelectric material of claim 1, wherein the population of inorganic nanocrystals comprises an atomic species.

7. The thermoelectric material of claim 6, wherein the population of inorganic nanocrystals is chosen from a group consisting of: Bi, Sb, and Te.

8. The thermoelectric material of claim 1, wherein the population of inorganic nanocrystals comprises a colloidal nanocrystal population.

9. The thermoelectric material of claim 1, wherein the population of inorganic nanocrystals comprises a metallic nanocrystal population.

10. The thermoelectric material of claim 1, further comprising a grain growth inhibitor.

11. The thermoelectric material of claim 10, wherein the grain growth inhibitor is chosen from a group comprising: tungsten, titanium, silver, oxygen, silicon, carbon, zirconium, and an oxidized surface of the population of ball-milled particles.

12. A method of making a thermoelectric material with enhanced thermoelectric (TE) performance, the method comprising:
mixing a population of ball-milled particles with a population of inorganic nanocrystals, wherein the inorganic nanocrystals act as a glue.

13. The method of claim 12, wherein the population of ball-milled particles comprises a semiconductor material.

14. The method of claim 12, wherein the population of inorganic nanocrystals comprises a semiconductor material.

15. The method of claim 12, further comprising:
consolidating the mixture of the population of ball-milled particles and the population of inorganic nanocrystals.

16. The method of claim 15, wherein the consolidating comprises at least one of a group comprising: hot pressing, low temperature pressing, and spark plasma sintering.

17. The method of claim 12, further comprising:
mixing a grain growth inhibitor with the population of ball-milled particles and the population of inorganic nanocrystals.

18. The method of claim 17, wherein the grain growth inhibitor is chosen from a group consisting of: tungsten, titanium, silver, oxygen, silicon, carbon, zirconium, and an oxidized surface of the population of ball-milled particles.
